(19) United States
(12) Patent Application Publication
(10) Pub. No.: US 2005/0077512 A1
(43) Pub. Date: Apr. 14, 2005

(54) Nitride semiconductors on silicon substrate and method of manufacturing the same

(75) Inventors: Suk-ho Yoon, Seoul (KR); Cheul-ro Lee, Jeollabuk-do (KR); Jeong-wook Lee, Gyeonggi-do (KR); Sung-sook Lee, Jeollabuk-do (KR)

Correspondence Address: BURNS DOANE SWECKER & MATHIS L L P, POST OFFICE BOX 1404, ALEXANDRIA, VA, 22313-1404, US

(73) Assignee: Samsung Electro-mechanics Co., Ltd., Gyeonggi-do (KR)

(21) Appl. No.: 10/949,469

(22) Filed: Sep. 27, 2004

(30) Foreign Application Priority Data
Oct. 13, 2003 (KR) 10-2003-0070984

(51) Int. Cl. H01L 29/08

(52) U.S. Cl. 257/40

(57) ABSTRACT

Provided is a nitride semiconductor formed on a Si substrate and a method of manufacturing the same. A buffer layer is formed on the silicon substrate, and an intermediate layer having voids is formed on the buffer layer. A planarizing layer is formed on the intermediate layer, and a nitride semiconductor layer is formed on the planarizing layer. Therefore, a nitride semiconductor in which the creation of crystal defects, dislocation or cracks is substantially decreased can be produced on a large scale at a low cost.

### BACKGROUND OF THE INVENTION

This application claims the priority of Korean Patent Application No. 2003-70984, filed on Oct. 13, 2003, in the Korean Intellectual Property Office, the disclosure of which is incorporated herein in its entirety by reference.

1. Field of the Invention

The present invention related to a nitride-based compound semiconductor and a method of growing a nitride compound semiconductor on a silicon substrate, and more particularly, to a nitride-based compound semiconductor formed on a silicon substrate without lattice defects and cracks because of an intermediate layer between the silicon substrate and a nitride-based compound semiconductor layer, and a method of manufacturing the same.

2. Description of the Related Art

In conventional blue and green light emitting devices, substrates used in forming compound semiconductor layers thereon are sapphire or SiC substrates, not GaN substrates due to the difficulty of manufacturing GaN substrates. However, the use of sapphire or SiC substrates results in high costs, low electric conductivity and thermal conductivity, and the mass production of devices is impossible to be realized because a large area cannot be grown. In addition, because sapphire and SiC substrates are insulators, these substrates have been applied only to devices having photoelectron characteristics. That is, these substrates cannot be applied to MEMS, NEWS and micro-OEIC devices having photoelectric characteristics and electric-electron composite characteristics. However, these disadvantages can be overcome by the use of silicon (Si) substrates. As a result, Si substrates can be used for various devices including the above-mentioned devices.

Despite this advantage, however, problems arise when a Group III nitride-based semiconductor layer, such as a GaN layer, is formed on the Si substrate. Due to the difference in thermal expansion coefficients of the Si substrate and GaN (GaN:5.59×10⁻⁶/K, Si:3.59×10⁻⁶/K ), tensile stress is generated when the Group III nitride-based semiconductor layer is cooled after being grown at a high temperature. Thus, crystal defects, dislocation, cracks and the like are created in a grown GaN layer. In particular, the cracks cause the inner structure of crystals to be fragile, degrading device characteristics. Accordingly, the Si substrate cannot be used for the growth of a Group III nitride semiconductor.

Many efforts have been made to prevent cracks. For example, buffer layers with different composition are repeatedly and sequentially grown to form a super lattice so as to prevent cracks. Examples of this method include low temperature AlN buffer layer growth (LT-AlN) (A. Watanabe et al., J. Cryst. Growth 128. 391(1993)), and low temperature GaN buffer layer growth (LT-GaN) (H. Ishikawa et al,. J. Cryst. Growth 189/190, 178 (1998)). However, in these cases, the cracks cannot be prevented perfectly.

Although an ex situ method (Y. Kawaguchi et al., Jpn. J. Appl. Phys. 37, L966 (1998)) such as ELOG or PENDO has been used, the prevention of cracks is impossible, and the manufacturing process of a device using this method is complicated, resulting in high manufacturing costs.

FIG. 1A illustrates a Group III nitride semiconductor formed on a Si substrate according to the prior art. A buffer layer 11 is formed on a Si substrate 10, and then GaN 12 is formed on the buffer layer 11 at a high temperature. A material for the buffer layer 11 is carefully selected to stably grow the GaN 12, taking thermal conductivities and crystal structures of the Si substrate 10 and the GaN 12 into account. However, even in this case, the lattice defects, dislocation and cracks 13 cannot be prevented, which is illustrated in FIG. 1B. FIG. 1B is an SEM image of a surface of the GaN 12 formed according to the method illustrated by FIG. 1A. Referring to FIG. 1B, numerous crystal defects 13 are formed on the surface of the GaN 12. The crystal defects ultimately result in the degradation of characteristics of completed semiconductor device.

### SUMMARY OF THE INVENTION

The present invention provides a nitride semiconductor in which the creation of crystal defects, dislocation or cracks is substantially decreased because a tensile stress, which can be generated between a Si substrate and a nitride semiconductor, is relaxed or removed, and a method of manufacturing the same.

According to an aspect of the present invention, there is provided a nitride semiconductor formed on a silicon substrate, the nitride semiconductor including the silicon substrate, an intermediate layer formed on the silicon substrate, the intermediate layer having a plurality of voids, a planarizing layer formed on the intermediate layer, and a nitride semiconductor formed on the planarizing layer.

The nitride semiconductor may further include a buffer layer interposed between the silicon substrate and the intermediate layer.

The intermediate layer, the planarizing layer and the nitride semiconductor layer may include a Group III nitride-based compound semiconductor material.

The planarizing layer may have a thickness of 100-500 nm.

According to an aspect of the present invention, there is provided a light emitting device including a silicon substrate; an intermediate layer formed on the silicon substrate; the intermediate layer having a plurality of voids; a planarizing layer formed on the intermediate layer; a first nitride semiconductor layer formed on the planarizing layer; an active layer, a second nitride semiconductor layer, and a first electrode layer sequentially formed on a portion of the first nitride semiconductor layer; and a second electrode layer formed on a portion of the first nitride semiconductor layer on which the active layer is not formed.

According to an aspect of the present invention, there is provided a method of manufacturing a nitride semiconductor formed on a silicon substrate, the method including forming an intermediate layer having voids on the silicon substrate, forming a planarizing layer on the intermediate layer, and forming a nitride-based semiconductor layer on the planarizing layer.

The method of manufacturing a nitride semiconductor formed on a silicon substrate may further include forming a buffer layer on the silicon substrate.

The forming an intermediated layer may be performed at a temperature of about 700-900° C., the forming a planarizing layer may be performed at a temperature of about 500-700° C., and the forming a nitride-based semiconductor layer may be performed at a temperature of 900-1200° C.

The planarizing layer may be formed to a thickness of 100-500 nm, and each step may be performed using a MOCVD process.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view illustrating the growth of a nitride semiconductor on a silicon substrate according to the prior art, and FIG. 1B is an SEM image of the surface of the nitride semiconductor illustrated in FIG. 1A;

FIG. 2 is a cross-sectional view illustrating the growth of a nitride semiconductor on a silicon substrate according to an embodiment of the present invention;

FIG. 3A is a cross-sectional view of a buffer layer and an intermediate layer formed on the silicon substrate, FIG. 3B is an SEM image of a surface of the intermediate layer, and FIG. 3C is an SEM image of a cross section of the buffer layer and the intermediate layer formed on the substrate.

FIG. 4A is a cross-sectional view of the buffer layer, the intermediate layer and the planarizing layer formed on the silicon substrate, and FIG. 4B is an SEM image of the planarizing layer;

FIG. 5A is a cross-sectional view of the buffer layer, the intermediate layer, the planarizing layer and a nitride semiconductor layer, FIG. 5B is an SEM image of a surface of the nitride semiconductor layer, and FIG. 5C is a cross section of the buffer layer, the intermediate layer, the planarizing layer, the nitride semiconductor layer, and the silicon substrate;

FIGS. 6A and 6B are graphs illustrating the results of high resolution X-ray diffraction analysis of the nitride semiconductor structure grown according to the prior art and according to the present invention; and

FIG. 7 is a cross-sectional view of a light emitting device according to an embodiment of the present invention.

### DETAILED DESCRIPTION OF THE INVENTION

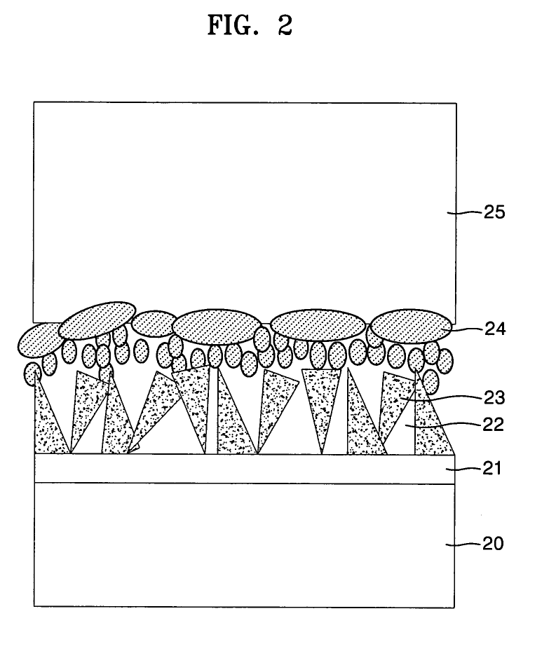

FIG. 2 is a cross-sectional view illustrating a nitride semiconductor grown on a Si substrate according to an embodiment of the present invention. Referring to FIG. 2, a buffer layer 21 is formed on a Si substrate, and an intermediate layer 23 having a plurality of voids 22 is formed on the buffer layer 21. A planarizing layer 24 is formed on the intermediate layer 23, and then a nitride compound 25 is formed on the planarizing layer 24.

The buffer layer 21 compensates for the wetting property because the nitride semiconductor material 25, for example GaN, is lack of the wetting property with respect to the Si substrate. The wetting property indicates the uniformity of an area density of a material formed from a base. When the wetting property is poor, planarization cannot be easily achieved because only a portion of the base can be grown. When a nitride-based compound such as GaN is formed on the Si substrate 20, the buffer layer 21 is interposed between those. The buffer layer 21 is not limited to specific materials, and can be selected according to the compound semiconductor formed.

The intermediate layer 23 having the voids 22 is formed on the buffer layer 21. The intermediate layer 23 is composed of a Group III nitride-based material. The voids 22 is formed by controlling the condition when forming the intermediate layer 23.

The planarizing layer 24 is formed on the intermediate layer 23. The planarizing layer 24 is composed of a nitride semiconductor material, of which the intermediate layer 23 is also composed. The planarizing layer 24 facilitates the forming of the nitride semiconductor layer 25 with uniform and stable characteristics, and does not have relatively large voids. However, the palnarizing layer 24 may have relatively small voids.

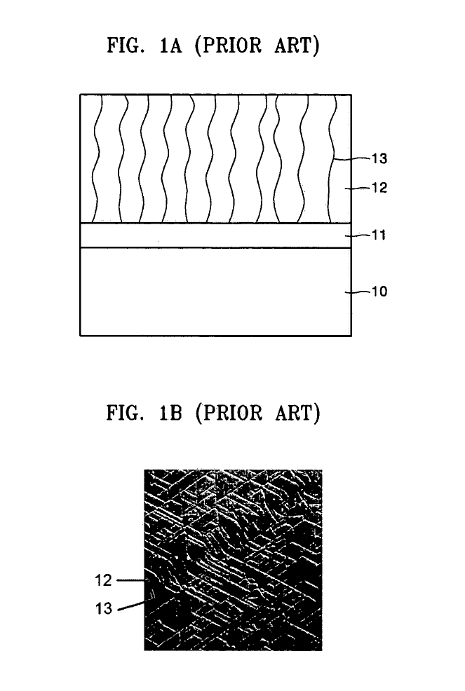

The nitride semiconductor layer 25 is formed on the planarizing layer 24. The generation of crystal defects, dislocation and cracks in the nitride semiconductor layer 25 is prevented as opposed to the prior art nitride semiconductor illustrated in FIG. 1A. This is because the voids 22 formed in the intermediate layer 23 reduce the tensile stress that can be generated between the Si substrate 20 and the nitride semiconductor layer 25. In addition, the buffer layer 21 and the planarizing layer 24 act as a buffer, and thus the nitride semiconductor layer 25 is stably grown.

A method of forming the nitride-based semiconductor formed on the Si substrate according to an embodiment of the present invention will now be described.

First, the buffer layer 21 is formed on the Si substrate 20. The buffer layer 21 improves the wetting property of nitride semiconductor materials on the Si substrate 20, and the buffer layer 21 can be grown to an appropriate thickness according to the material that the buffer layer 21 is composed of.

Next, the intermediate layer 23 having the voids 22 is formed on the buffer layer 21. The intermediated layer 23 is composed of a Group III nitride-based material. If the intermediate layer 23 is composed of GaN, it may be formed at a temperature of 700-900° C. In this case, the intermediate layer 23 is grown with a pyramid-like form due to the lack of the wetting property. In addition, the intermediate layer 23 is grown with a rough surface due to its seriously bent surface. Therefore, the voids 22 are formed in the intermediate layer 23.

Next, the planarizing layer 24 is formed on an upper portion of the intermediate layer 23. The planarizing layer 24 is composed of the Group III nitride-based material. If the planarizing layer 24 is composed of GaN, it may be formed at a temperature of 500-700° C. A thickness of the planarizing layer 24 is 100-500 nm, preferably 200-400 nm. As the planarizing layer 24 is grown on the intermediate layer 23, curves formed on the surface of the intermediate layer 23 gradually disappears, thereby obtaining a planarizing layer.

Then, the nitride semiconductor layer 25 is formed on an upper surface of the planarizing layer 24. The thickness of the nitride semiconductor layer 25 can be controlled according to its purpose, and in general the thickness is a several μm. If the nitride semiconductor layer 25 is composed of GaN, it may be grown at a temperature of 900-1200° C. In the nitride semiconductor layer 25 grown as described above, the tensile stress in the region between the Si substrate 20 and the nitride semiconductor layer 25 is decreased due to the voids 22 in the intermediate layer 23. Thus, problems such as crystal defects, dislocation or cracks, which can be formed during a cooling process after the above process is completed, can be prevented.

A process of forming a nitride semiconductor on a silicon substrate according to an embodiment of the present invention using metal-organic chemical vapor deposition (MOCVD) will be described with reference to SEM images.

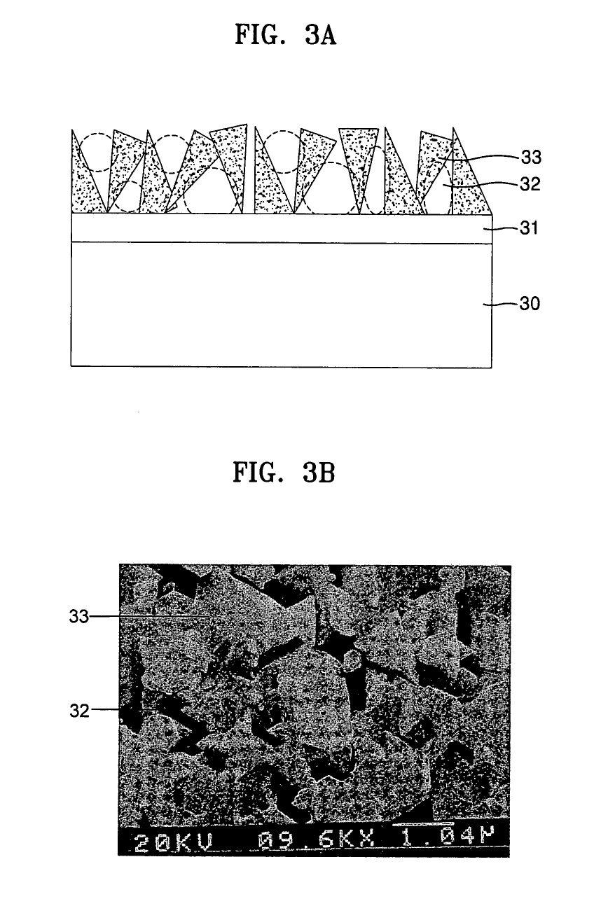

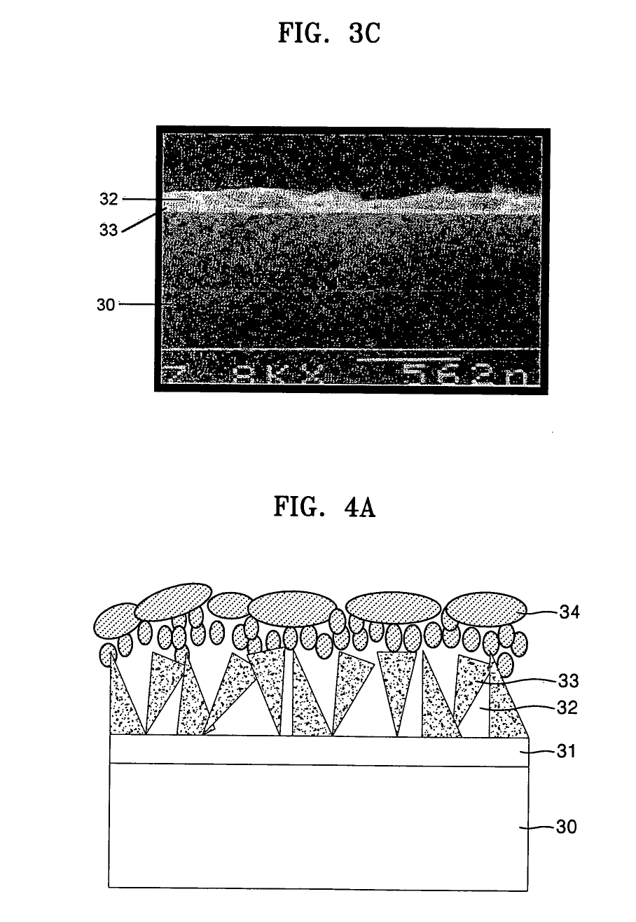

Referring to FIG. 3A, before forming a nitride semiconductor layer 35 on a Si substrate 30, a buffer layer 31 is formed to improve a wetting property of the nitride semiconductor layer 35 with respect to the Si substrate 30. Next, GaN is grown to form an intermediate layer 33 to a thickness of about 300 nm at about 800° C. The GaN grown for the intermediate layer 33 lacks the wetting property with respect to the Si substrate 30 and therefore epitaxial growth cannot be performed. As a result, the GaN has, as illustrated in FIG. 3A, a pyramid-like form having a rough surface, resulting in a plurality of voids 32 in the intermediate layer 33.

FIG. 3B is an SEM image of the surface of the intermediate layer 33 when it is grown as described above. Referring to FIG. 3B, the surface of the intermediate layer 33 is very rough, and the density of the voids illustrated by dark portions is very high. FIG. 3C is an SEM image of the cross section of the structure after the intermediate layer 33 is formed. Referring to FIG. 3C, the intermediate layer 33 having the voids 32 formed on the substrate 30 is much brighter than other layers.

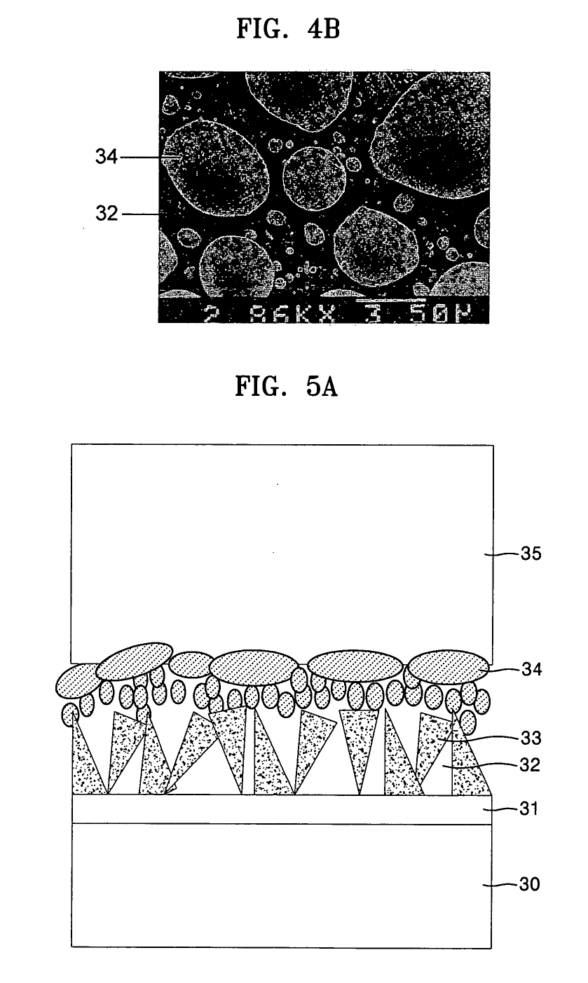

Referring to FIG. 4A, GaN is grown on the intermediate layer 33 to form a planarizing layer 34. The temperature for the growing is about 560° C., which is lower than the growth temperature of the intermediate layer 33, and the thickness of the planarizing layer 34 is about 300 nm. The planarizing layer 34 fills part of the voids 32 in the intermediate layer 33 without completely filling. FIG. 4B is an SEM image of a surface of the planarizing layer 34 grown as described above. Referring to FIG. 4B, the planarizing layer 34 on the intermediate layer 33 having the voids 32 gradually grows.

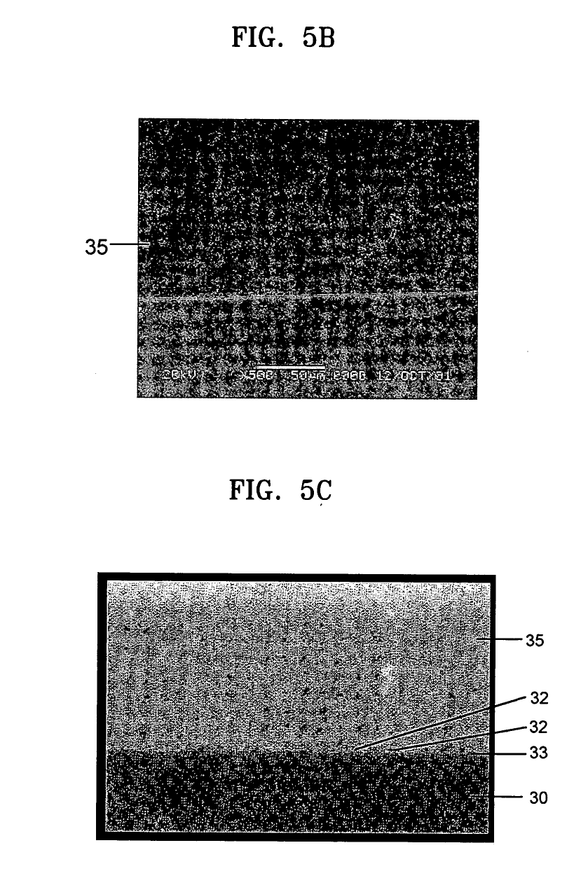

As illustrated in FIG. 5A, the nitride semiconductor layer 35 is formed on an upper portion of the planarizing layer 34 at a temperature of about 1050° C., and is grown to a thickness of a several μm. An SEM image of a surface of the nitride semiconductor layer 35 is illustrated in FIG. 5B. Referring to FIG. 5B, the creation of cracks in the nitride semiconductor layer was suppressed. Due to the voids 32 formed in the intermediate layer 33, the tensile stress in the nitride semiconductor layer 35 is relaxed and a stable structure is obtained. After the nitride semiconductor layer 35 is formed, an SEM image of a cross section thereof was taken. The SEM image is illustrated in FIG. 5C. Referring to FIG. 5C, the intermediate layer 33 having the voids 32 interposed between the silicon substrate 30 and the nitride semiconductor layer 35 can be seen.

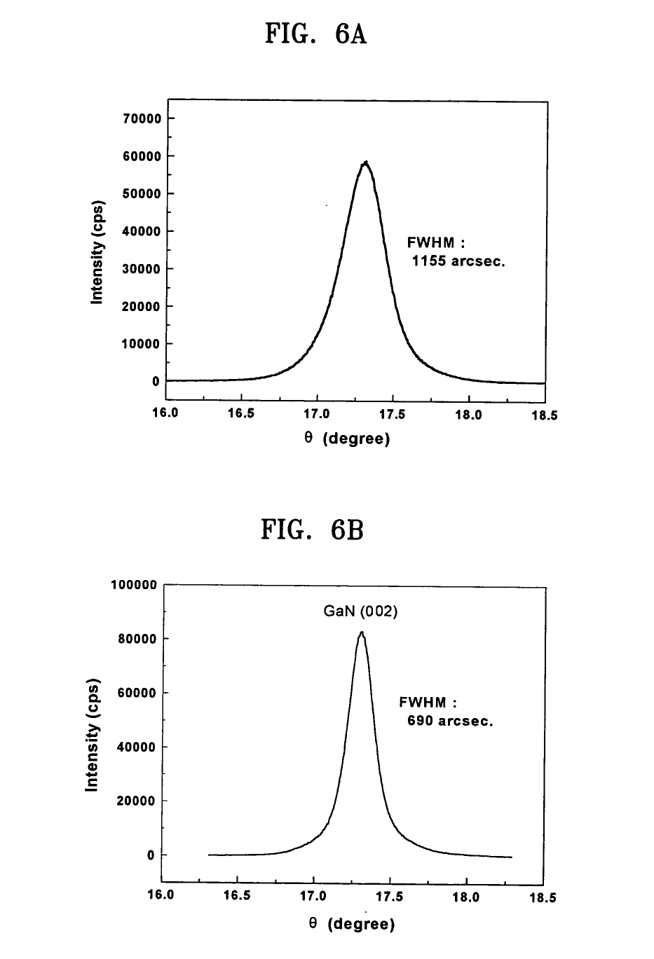

For the analysis for the structure of a semiconductor manufactured by the above process, a High Resolution X-Ray Diffraction (HR×RD) was used to compare the structures of semiconductors according to an embodiment of the present invention and according to the prior art. The comparison is illustrated in FIGS. 6A and 6B. Referring to FIGS. 6A and 6B, the X-ray diffraction intensity of the (002) plane of the GaN grown according to the prior art is 58000 cps (FIG. 6A), and the X-ray diffraction intensity of the (002) plane of the GaN grown according to an embodiment of the present invention is 82000 cps (FIG. 6B). The full width half maximum (FWHM) value of the graph of FIG. 6A is 1155 arcsec while that of the graph of FIG. 6B is 690 arcsec. Therefore, the crystal growth of the GaN grown according to an embodiment of the present invention is very stable compared to that of the prior art.

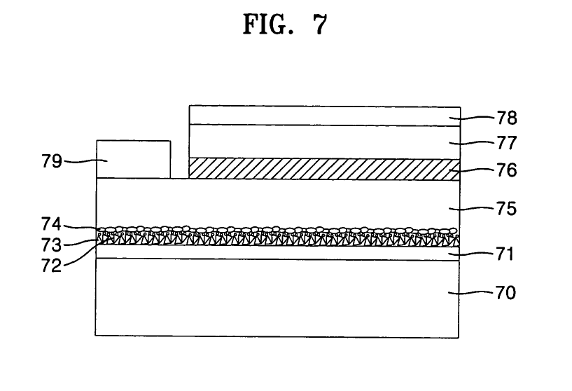

FIG. 7 illustrates a light emitting device according to an embodiment of the present invention. A buffer layer 71 is formed on a substrate 70. An intermediate layer 73 having a plurality of voids 72 is formed on the buffer layer 71. A planarizing layer 74 is formed on the intermediate layer 73. A stabilized nitride-based compound layer 75 is formed on the planarizing layer 74. If the nitride-based compound layer 75 is composed of a n-type nitride-based compound, an active layer 76, a p type nitride-based compound layer 77 and a p type electrode layer 78 are sequentially formed on a portion of an upper surface of the n-type nitride-based compound layer 75. An n-type electrode layer 79 is formed on a portion of the upper surface where the active layer is not formed. Because the nitride-based compound layer 75 has enhanced crystalline characteristics due to the absence of cracks and the decrease in lattice defects and dislocation in the intermediate layer 73 having the voids 72, a nitride-based compound semiconductor device having high performance and a high yield rate can be manufactured.

As described above, according to embodiments of the present invention, a nitride semiconductor in which the creation of crystal defects, dislocation or cracks in a nitride semiconductor can be prevented due to the relaxation of tensile stress that may occur between a Si substrate and a nitride semiconductor.

Therefore, manufacturing costs are low because a low-priced Si substrate can be used without any technical disadvantage. A Si substrate having a large area can be used to decrease the manufacturing costs, and the use of a Si substrate with high electric conductivity and thermal conductivity results in the improvement of a stoppage inner pressure and inner characteristics of devices, thereby improving the reliability and lifespan of the devices. The nitride semiconductor can be applied to state-of-the-art information photoelectric devices having photoelectric characteristics and electric-electron composite characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A nitride semiconductor comprising:
a silicon substrate;
an intermediate layer formed on the silicon substrate, the intermediate layer having a plurality of voids;
a planarizing layer formed on the intermediate layer; and
a nitride semiconductor formed on the planarizing layer.

2. The nitride semiconductor of claim 1, further comprising a buffer layer interposed between the silicon substrate and the intermediate layer.

3. The nitride semiconductor of claim 1, wherein the intermediate layer, the planarizing layer and the nitride semiconductor layer include a Group III nitride-based compound semiconductor material.

4. The nitride semiconductor of claim 3, wherein the intermediate layer, the planarizing layer and the nitride semiconductor layer include GaN.

5. The nitride semiconductor of claim 1, wherein the planarizing layer has a thickness of 100-500 nm.

6. A light emitting device comprising:
a silicon substrate;
an intermediate layer formed on the silicon substrate, the intermediate layer having a plurality of voids;
a planarizing layer formed on the intermediate layer;
a first nitride semiconductor layer formed on the planarizing layer;
an active layer, a second nitride semiconductor layer and a first electrode layer sequentially formed on a portion of the first nitride semiconductor layer; and
a second electrode layer formed on a portion of the first nitride semiconductor layer on which the active layer is not formed.

7. The light emitting device of claim 6, further comprising a buffer layer interposed between the silicon substrate and the intermediate layer.

8. A method of forming a nitride semiconductor on a silicon substrate, the method comprising:
forming an intermediate layer having voids on the silicon substrate;
forming a planarizing layer on the intermediate layer; and
forming a nitride-based semiconductor layer on the planarizing layer.

9. The method of claim 8, further comprising forming a buffer layer on the silicon substrate.

10. The method of claim 8, wherein the intermediate layer, the planarizing layer and the nitride-based semiconductor layer include a Group III nitride-based compound semiconductor.

11. The method of claim 10, wherein the Group III nitride-based compound semiconductor is GaN.

12. The method of claim 11, wherein the forming an intermediated layer is performed at a temperature of about 700-900° C.

13. The method of claim 11, wherein the forming a planarizing layer is performed at a temperature of about 500-700° C.

14. The method of claim 11, wherein the planarizing layer is formed to a thickness of 100-500 nm.

15. The method of claim 11, wherein the forming a nitride-based semiconductor layer is performed at a temperature of 900-1200° C.

16. The method of claim 11, wherein the forming of each of the layers is performed using a MOCVD process.
